(19) United States
(12) Patent Application Publication
(10) Pub. No.: US 2024/0203984 A1
(43) Pub. Date: Jun. 20, 2024

(54) STACKED TRANSISTORS WITH STEPPED CONTACTS

(71) Applicant: INTERNATIONAL BUSINESS MACHINES CORPORATION, Armonk, NY (US)

(72) Inventors: Su Chen Fan, Cohoes, NY (US); Indira Seshadri, Niskayuna, NY (US); Jay William Strane, Warwick, NY (US); Stuart Sieg, Albany, NY (US)

(21) Appl. No.: 18/067,968

(22) Filed: Dec. 19, 2022

(51) Int. Cl. H01L 27/088; H01L 21/8234; H01L 29/06; H01L 29/423; H01L 29/775

(52) U.S. Cl. CPC H01L 27/088; H01L 21/823412; H01L 29/0673; H01L 29/42392; H01L 29/775

(57) ABSTRACT

Semiconductor devices and methods of forming the same include a lower semiconductor device over a substrate, the lower semiconductor device having a first width. An upper semiconductor device is over the lower semiconductor device. The upper semiconductor device has a second width smaller than the first width. A dielectric structure is over the lower semiconductor device and has a first sidewall that faces the upper semiconductor device and a second sidewall that aligns vertically with a sidewall of the lower semiconductor device.

### BACKGROUND

The present invention generally relates to semiconductor device fabrication and, more particularly, to the fabrication of stacked nanosheet transistors.

Stacked transistor devices may be used to increase the areal density of devices on a chip. Additionally, the close proximity of the overlying and underlying devices can be useful when forming paired devices, such as complementary semiconductor devices that include two devices of opposing polarity. However, positioning transistors above one another can make it challenging to form signal- and power-bearing connections to the gate and source/drain structures of the underlying device.

### SUMMARY

A semiconductor device includes a lower semiconductor device over a substrate, the lower semiconductor device having a first width. An upper semiconductor device is over the lower semiconductor device. The upper semiconductor device has a second width smaller than the first width. A dielectric structure is over the lower semiconductor device and has a first sidewall that faces the upper semiconductor device and a second sidewall that aligns vertically with a sidewall of the lower semiconductor device.

A semiconductor device includes a lower semiconductor device over a substrate, the lower semiconductor device having a first width. An upper semiconductor device is over the lower semiconductor device. The upper semiconductor device has a second width smaller than the first width. A dielectric liner is on a side of a channel layer of the upper semiconductor device and is formed from a first dielectric material. A dielectric structure is over the lower semiconductor device. The dielectric structure has a first sidewall that faces the upper semiconductor device and the dielectric liner and a second sidewall that aligns vertically with a sidewall of the lower semiconductor device and is formed from a second dielectric material different from the first dielectric material.

A method of forming a semiconductor device includes etching an upper stack of layers from a series of alternating semiconductor layers using a top dielectric layer as a mask. A dielectric spacer is formed on a sidewall of the upper stack of layers. A lower stack of layers is etched from the series of alternating semiconductor layers, using the top dielectric layer and the dielectric spacer as a mask. A lower transistor is formed from the lower stack of layers. An upper transistor is formed from the upper stack of layers.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a step in the fabrication of stacked transistors with stepped contacts, showing a set of different cross-sectional planes, in accordance with an embodiment of the present invention;

FIG. 2 is a set of cross-sectional views of a step in the formation of stacked transistors with stepped contacts, showing the formation of a mask over a set of alternating semiconductor layers, in accordance with an embodiment of the present invention;

FIG. 3 is a set of cross-sectional views of a step in the formation of stacked transistors with stepped contacts, showing the formation of an upper stack by etching the set of alternating semiconductor layers, in accordance with an embodiment of the present invention;

FIG. 4 is a set of cross-sectional views of a step in the formation of stacked transistors with stepped contacts, showing the formation of an upper protective layer and a dielectric layer over the upper stack, in accordance with an embodiment of the present invention;

FIG. 5 is a set of cross-sectional views of a step in the formation of stacked transistors with stepped contacts, showing the formation of a mask over the dielectric layer on one side of the upper stack, in accordance with an embodiment of the present invention;

FIG. 6 is a set of cross-sectional views of a step in the formation of stacked transistors with stepped contacts, showing an etch of the dielectric layer to remove material not covered by the mask, in accordance with an embodiment of the present invention;

FIG. 7 is a set of cross-sectional views of a step in the formation of stacked transistors with stepped contacts, showing the removal of horizontal portions of the dielectric layer using an anisotropic etch, in accordance with an embodiment of the present invention;

FIG. 8 is a set of cross-sectional views of a step in the formation of stacked transistors with stepped contacts, showing the formation of a mask over the upper stack, in accordance with an embodiment of the present invention;

FIG. 9 is a set of cross-sectional views of a step in the formation of stacked transistors with stepped contacts, showing the removal of portions of the dielectric layer that are not covered by the mask, in accordance with an embodiment of the present invention;

FIG. 10 is a set of cross-sectional views of a step in the formation of stacked transistors with stepped contacts, showing the formation of a lower stack from the alternating layers using the remaining portion of the dielectric layer and the upper stack as a mask, in accordance with an embodiment of the present invention;

FIG. 11 is a set of cross-sectional views of a step in the formation of stacked transistors with stepped contacts, showing the formation of upper and lower transistor devices from the upper and lower stacks, with the remaining portion of the dielectric layer remaining in a gate region, in accordance with an embodiment of the present invention; and

FIG. 12 is a block/flow diagram of a method for fabricating stacked transistors with stepped contacts, in accordance with an embodiment of the present invention.

### DETAILED DESCRIPTION

A stepped structure may be used when forming stacked transistors, for example by trimming the upper transistor area to expose a portion of the lower transistor area. The stepped profile makes it possible to form conductive contacts with vias that reach straight down to the underlying device. Rather than using a lithography-etch-lithography-etch process to define the locations of the upper and lower devices, a placeholder dielectric may be formed on a sidewall of the upper transistor and may be used as a mask to define the area of the lower transistor. Using the placeholder dielectric as a mask prevents mask placement errors that may arise when the lithography placement resolution comes close to the difference in size between the top transistor and the bottom transistor.

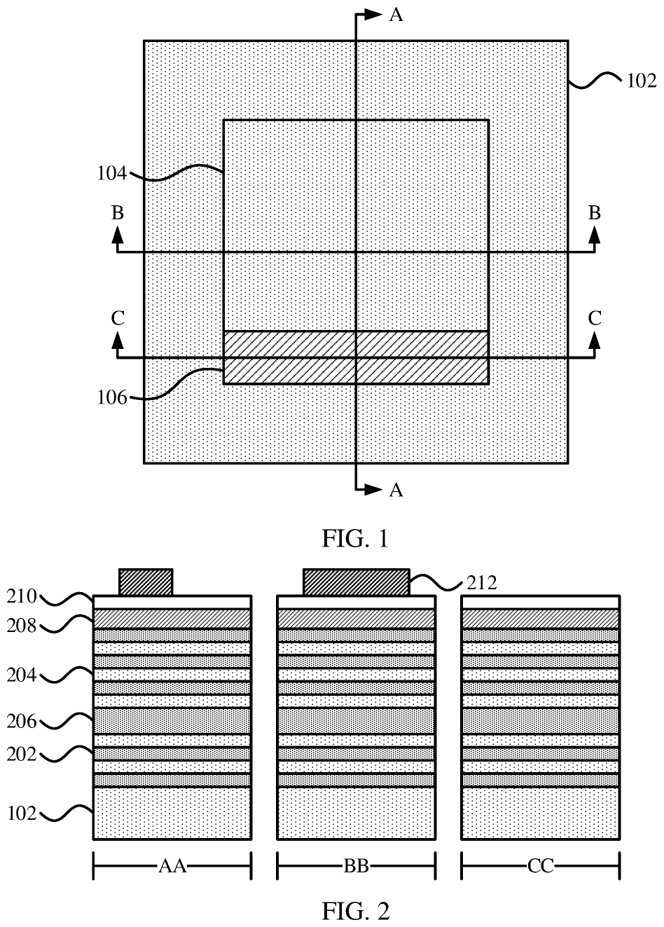

Referring now to FIG. 1, a top-down view of a step in the fabrication of stacked semiconductor devices with a stepped profile is shown. This top-down view illustrates multiple cross-sectional planes that will be used hereinafter to show different views of steps in the fabrication process. A semiconductor substrate 102 is shown, with a top channel layer 104 and a sacrificial dielectric placeholder 106 on a sidewall of the top channel layer 104. Bottom channel layers are positioned underneath the top channel layer 104 and the sacrificial dielectric placeholder 106 and are not shown in this view.

A first cross-section, AA, establishes a plane that cuts vertically through the top channel layer 104 and the bottom channel layer, and further cuts through the dielectric placeholder 106. A second cross-section, BB, establishes a plane that cuts vertically through the top channel layer 104 and the bottom channel layer, parallel to the dielectric placeholder 106 but not through the dielectric placeholder 106. A third cross-section, CC, establishes a plane that cuts vertically through the bottom channel layer and the dielectric placeholder 106, but does not cut through the top channel layer 104.

As shown, the cross-section AA cuts through what may become a gate/channel section of the top transistor device and the bottom transistor device. For the steps described herein, the structures and processes shown in the gate/channel section may be identical to those of the source/drain section. However, it may be understood that these different regions may undergo different processes to produce the different functional structures of a transistor device.

Referring now to FIG. 2, a set of cross-sectional views is shown of a step in the fabrication of stacked semiconductor devices. A stack of semiconductor layers may be epitaxially grown from a top surface of semiconductor substrate 102. The stack of semiconductor layers may include alternating sacrificial semiconductor layers 202 and channel layers 204, with each successive semiconductor layer being epitaxially grown from the top surface of the semiconductor layer before it.

A buffer layer 206 may be formed from the same semiconductor material as the sacrificial semiconductor layers 202 to separate channels of the top device from channels of the bottom device. In some cases, the buffer layer 206 may include a dielectric layer that electrically separates the top set of layers from the bottom set of layers, or a layer of silicon germanium. The buffer layer 206 may have a thickness that is between about 1.5-2 times greater than a thickness of the sacrificial semiconductor layers 202.

A mask layer 208 may be formed over the stack of alternating semiconductor layers. The mask layer 208 may be formed from any appropriate masking material, and may include multiple layers of such material. For example, the mask layer 208 may include a layer of a first dielectric material (e.g., silicon nitride) sandwiched between layers of a second dielectric material (e.g., silicon dioxide). A layer of amorphous silicon 210 may be formed over the mask layer 208. A lithographic pattern 212 may then be formed over the amorphous silicon 210, and may be used to establish a location of a top transistor device.

The semiconductor substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate.

As noted above, the stack of alternating semiconductor layers may be epitaxially grown from the top surface of the semiconductor substrate 102. The terms “epitaxial growth” and “epitaxial deposition” are used herein to refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. Thus, for example, if the semiconductor substrate 102 is formed from silicon, then the sacrificial semiconductor layers 202 may include a silicon germanium material and the channel layers 204 may include silicon, as these materials have similar crystalline structure. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The pattern 212 may be formed using any appropriate photolithographic process. For example, the pattern 212 may be produced by applying a photoresist to the surface to be etched. The photoresist may be exposed to a pattern of radiation, which may for example cure the exposed part of the photoresist. The pattern may be developed into the photoresist utilizing a resist developer that removes the portion of the photoresist material that was not cured. The result is a pattern 212 of material that covers and protects an area of the underlying surface(s).

Referring now to FIG. 3, a set of cross-sectional views is shown of a step in the fabrication of stacked semiconductor devices. A selective anisotropic etch is used etch the mask layer 208 according to the pattern 212, forming a mask 302. A further selective anisotropic etch can be used to remove material from the stack of alternating semiconductor layers in regions that are not protected by the mask 212. The etch may be timed to stop in the buffer layer 206, or alternating selective etches may be used to ensure that the etch does not penetrate past the buffer layer 206. The etch thereby produces an upper stack 304 from the alternating semiconductor layers above the buffer layer 206. In some cases, the second anisotropic etch may partially etch into the buffer layer 206, which will be removed in a subsequent step.

As used herein, the term “selective” in reference to a material removal process denotes that the rate of material removal for a first material is greater than the rate of removal for at least another material of the structure to which the material removal process is being applied. Thus, the selective anisotropic etches described with respect to the formation of the upper stack 304 may remove the semiconductor material of the alternating semiconductor layers, without substantially damaging the material of the mask 302.

The anisotropic etches may include, for example, reactive ion etching (RIE). RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface.

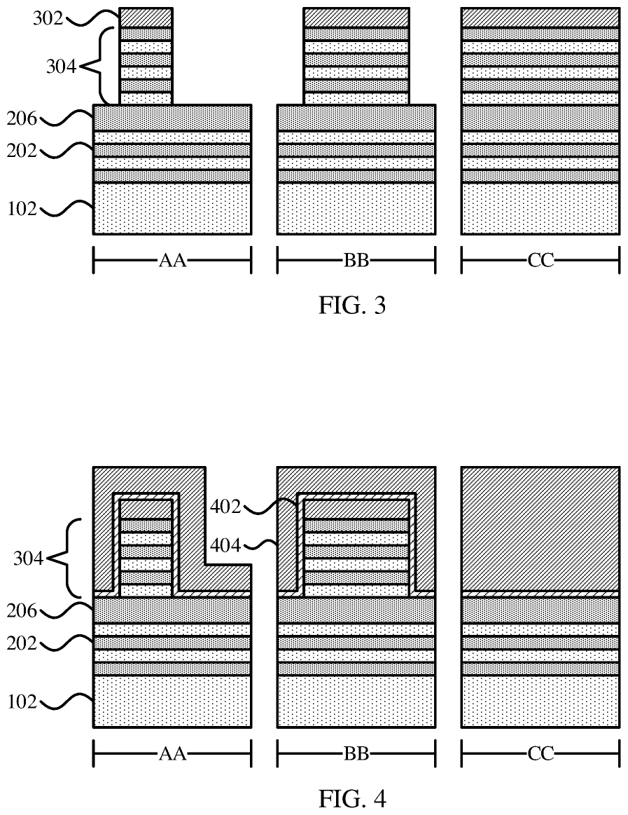

Referring now to FIG. 4, a set of cross-sectional views is shown of a step in the fabrication of stacked semiconductor devices. An upper protective layer 402 may be conformally deposited over the upper stack 304 using any appropriate conformal deposition process. The upper protective layer 402 may include, for example, any appropriate dielectric material, such as silicon dioxide, silicon nitride, aluminum oxide, titanium oxide, or silicon carbide that can be selectively removed with respect to a hardmask. The upper protective layer 402 protects the upper stack 304 during subsequent deposition processes that focus on the lower device.

A layer 404 of dielectric material is conformally deposited over the upper protective layer 402. The layer 404 of dielectric material may include any dielectric material with appropriate etch selectivity relative to the other materials of the device, such as silicon nitride (SiN), silicoboron carbonitride (SiCBN), silicon oxycarbonitride (SiOCN), or any other appropriate dielectric material that has etch selectivity with respect to silicon dioxide. It is specifically contemplated that the dielectric layer 404 may be formed from a low-k dielectric material. A low-k dielectric is one that has a dielectric constant lower than that of silicon dioxide. A low-k dielectric may be used to, e.g., minimize a parasitic capacitance resulting from the presence of a dielectric spacer within the gate conductor of a device.

The dielectric layer 404 may be deposited to a thickness that corresponds to a difference in the ultimate size between the upper device and the lower device, as the layer 404 will form part of a mask that is used to define the size of the lower device. As seen in cross-section CC, the dielectric material of the layer 404 may occupy the space at the side of the upper stack 304.

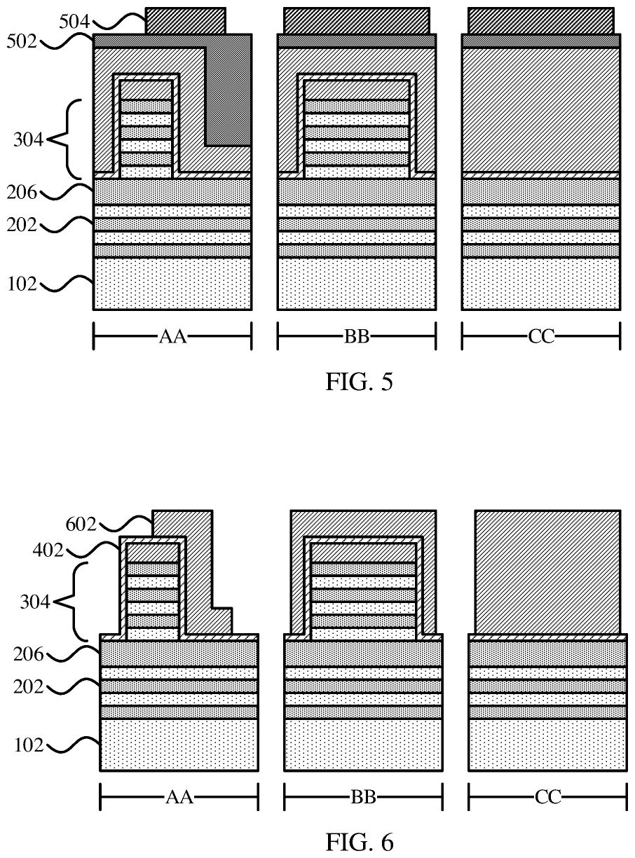

Referring now to FIG. 5, a set of cross-sectional views is shown of a step in the fabrication of stacked semiconductor devices. An organic planarizing layer (OPL) 502 may be deposited over the exposed structures using any appropriate deposition process. A mask 504 may then be formed over the OPL 502 by any appropriate photolithographic process. The mask 504 may overlap with the upper stack 304, and may further hang past the edge of the upper stack 304, as shown in cross-section AA. Notably, the mask 504 leaves an opposing edge of the upper stack 304 uncovered, so that the dielectric layer 404 may be removed in that area.

Referring now to FIG. 6, a set of cross-sectional views is shown of a step in the fabrication of stacked semiconductor devices. A selective anisotropic etch is used to remove material from the OPL 502 and the layer 404 of dielectric material, leaving behind dielectric 602. The etch stops on the upper protective layer 402, so that the etch does not damage the underlying layers of semiconductor material. After the etch, the mask 504 and any remaining parts of the OPL 502 may be removed to expose the top surface of the dielectric 602. As shown in cross-sections AA and BB, the dielectric 602 may be present on multiple sidewalls of the upper stack 304 at this stage of the process, but leaves at least one sidewall exposed.

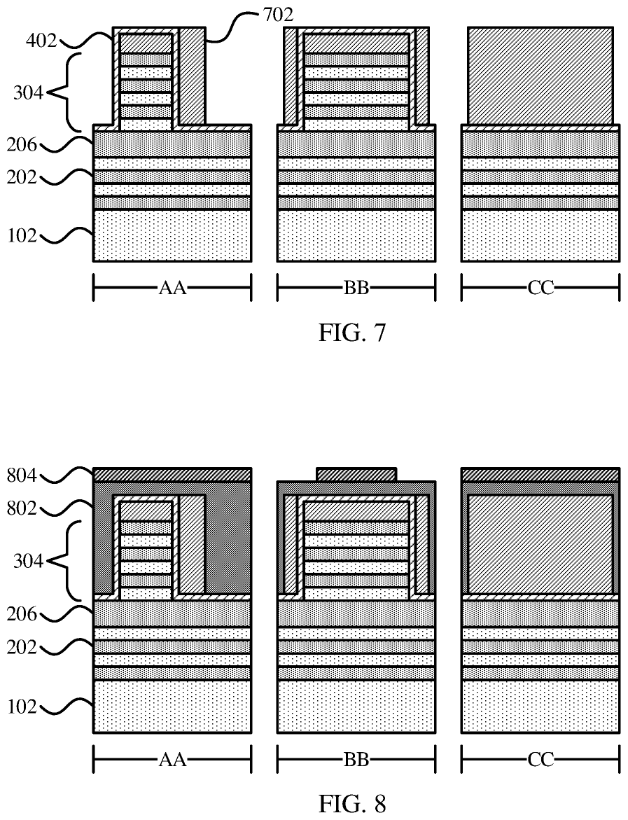

Referring now to FIG. 7, a set of cross-sectional views is shown of a step in the fabrication of stacked semiconductor devices. A selective anisotropic etch may be used to remove material from the dielectric 602 that is on horizontal surfaces, leaving behind dielectric spacer 702 on the sidewall of the upper stack 304. Portions of the dielectric 602 on the sidewall of the upper stack 304 remain after the etch, having a vertical thickness that is not fully removed by the anisotropic etch. The dielectric spacer 702 is shown as having a height equal to a height of the top surface of the upper protective layer 402, but may be reduced to a lower height by applying the anisotropic etch for a longer time.

Referring now to FIG. 8, a set of cross-sectional views is shown of a step in the fabrication of stacked semiconductor devices. An OPL 802 is deposited around the upper stack 304 and a photoresist mask 804 is patterned on top of the OPL 802. As shown in cross-section BB, the photoresist mask 804 exposes a portion of the OPL 802 above the dielectric spacer 702 at side edges of the upper stack 304, while the center part remains covered. As shown in cross-sections AA and CC, the photoresist mask 804 may cover at least part of the dielectric spacer 702.

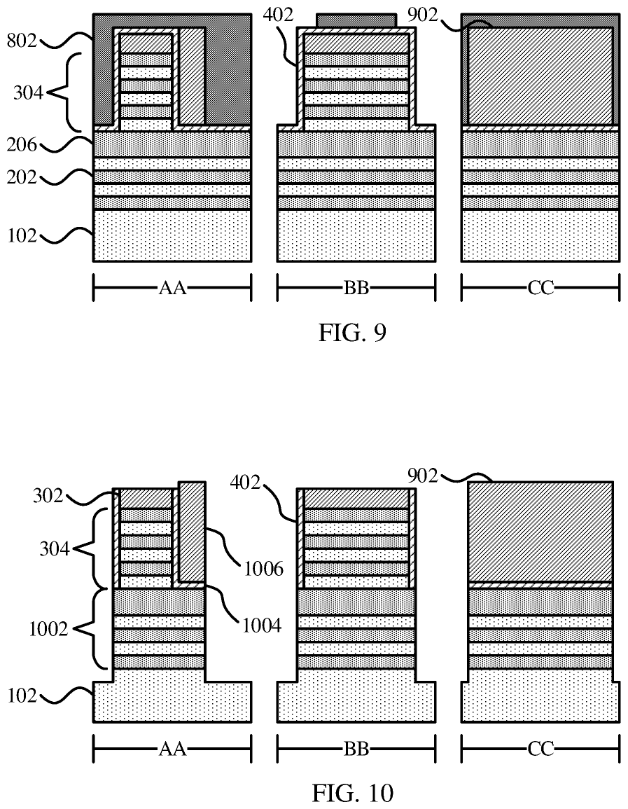

Referring now to FIG. 9, a set of cross-sectional views is shown of a step in the fabrication of stacked semiconductor devices. A selective anisotropic etch is used to etch away the exposed portions of the OPL 802, leaving behind those portions which are covered by the photoresist mask 804. A further selective anisotropic etch is used to remove exposed portions of the dielectric spacer 702, leaving the spacer 802 in regions that remain covered by the OPL 802. As shown in cross-section BB, the upper protective layer 402 is exposed at sides of the upper stack 304.

Referring now to FIG. 10, a set of cross-sectional views is shown of a step in the fabrication of stacked semiconductor devices. The remains of the OPL 802 are removed using any appropriate etching or ashing process to expose the upper protective layer 402 and the remaining portions of the dielectric spacer 902. A selective anisotropic etch is used to remove the upper protective layer 402 from horizontal surfaces, thereby exposing mask 302 and the top surface of the buffer layer 206.

The upper stack 304, the dielectric spacer 902, and the remaining portions of the upper protective layer 402 are used as a mask for one or more selective anisotropic etches that remove material from the buffer layer 206 and the semiconductor layers beneath it. The etch(es) remove semiconductor material from the alternating semiconductor layers to form lower stack 1002, and may further cut into the top surface of the semiconductor substrate 102, for example establishing shallow trench isolation (STI) regions around the lower stack 1002.

Although the stepped profile is shown with a single dielectric spacer 902 on a single side of the upper stack 304, it should be understood that a similar dielectric spacer may be formed on the other side of the upper stack 304, so that there are steps on both sides of the device.

The remaining portions of the dielectric spacer 702 are shown as dielectric remnant 1006. The dielectric remnant 1006 has a sidewall that vertically aligns with a sidewall of the lower stack 1002 and has a height that extends above the upper stack 304. Between the dielectric remnant 1006 and the upper stack 304 is a remaining portion of the upper protective layer 402, shown as dielectric liner 1004. The dielectric liner 1004 has an ‘L’-shaped profile, following the stepped contour of the upper stack 304 on the lower stack 1002. One sidewall of the dielectric liner 1004 is on the sidewall of the upper stack 304, while the other sidewall of the dielectric liner 1004 aligns vertically with the sidewall of the lower stack 1002 and the dielectric remnant 1006. The dielectric liner 1004 and the dielectric remnant 1006 may have top surfaces at different heights relative to the substrate 102. The dielectric liner 1004 may have a bottom surface that aligns horizontally with a bottom surface of a lowermost channel layer in the upper stack 304.

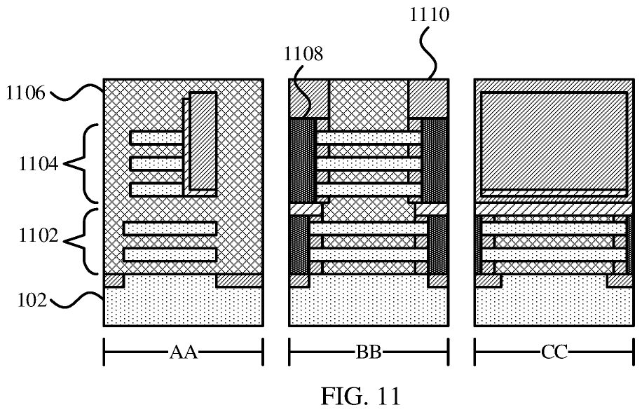

Referring now to FIG. 11, a set of cross-sectional views is shown of a step in the fabrication of stacked semiconductor devices. At this stage, additional steps may be performed to complete the top and bottom transistor devices. For example, source/drain structures 1108 may be epitaxially grown from exposed side surfaces of the channel layers in the lower stack 1002 to form lower device 1102. The bottom source/drain structures may be doped to form any appropriate device type (e.g., p-type or n-type), for example by in situ doping. The upper protective layer 402 and the mask layer 302 may be removed from those areas where it is not protected by the dielectric spacer 902, thereby exposing the upper stack 304, and source/drain structures 1108 may be epitaxially grown therefrom using any appropriately polarized dopant (e.g., n-type or p-type) to form upper device 1104. The lower device 1102 may be masked while the upper source/drain structures are formed to prevent that epitaxial growth process from interfering with the lower source/drain structures.

After formation of the respective source/drain structures 1108, the sacrificial layers may be selectively etched away using an isotropic etch that leaves the semiconductor material of the channel layers 204 relatively undamaged. This etch may further remove remaining portions of the buffer layer 206 between the upper device 1104 and the lower device 1102.

A gate stack 1106 be formed to make contact with the channel layers of each device, for example including a gate dielectric layer (not shown), an optional work function metal (not shown), and a gate conductor. The gate stack 1106 may join the gate regions of the top device 1104 and the bottom device 1102 as shown, or may be separated into two separate gates for the respective devices. An interlayer dielectric 1110 may be deposited around the upper device 1104 and the lower device 1102, and contacts may be formed therethrough to make appropriate electrical contact with the structures of the top device 1104 and the bottom device 1102.

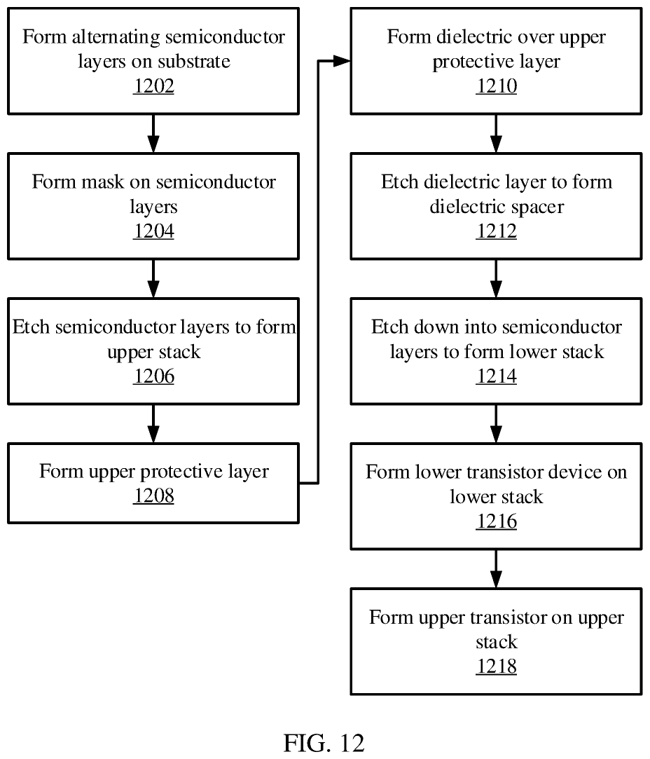

Referring now to FIG. 12, a method of fabricating stacked semiconductor devices with a stepped profile is shown. Block 1202 forms alternating semiconductor layers on a substrate 102. The alternating semiconductor layers may include sacrificial semiconductor layers formed from, e.g., silicon germanium, and channel layers formed from, e.g., silicon. Block 1202 may use alternating epitaxial growth processes to form the alternating semiconductor layers.

Block 1204 forms a mask 302 on the alternating semiconductor layers. The mask 302 may be formed by, e.g., depositing one or more layers of dielectric material over the alternating semiconductor layers. The one or more layers of dielectric material may include, for example, a layer of silicon nitride between layers of silicon dioxide. The mask 302 may be etched from these layers using a photolithographic mask 212 and a selective anisotropic etch that stops on the semiconductor layers.

Block 1206 etches the alternating semiconductor layers, using a selective anisotropic etch to remove material from the alternating semiconductor layers in areas that are not protected by the mask 302. The etch may be timed to stop in the buffer layer 206, thereby creating upper stack 304 of alternating semiconductor layers on the buffer layer 206.

Block 1208 forms upper protective layer 402 on the upper stack 304, for example by conformally depositing a dielectric material. Exemplary deposition processes include, e.g., chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Block 1210 forms a dielectric layer 404 over the upper protective layer 402 using a conformal deposition process. The dielectric layer 404 may be formed to any appropriate thickness, which corresponds to a difference in the size of an upper device and a lower device being formed. Block 1212 etches the dielectric layer 404 to form dielectric spacer 702. Block 1212 may form an OPL 502 and mask 504 over the dielectric layer 404, using the mask 504 to define a protected region of the dielectric layer. A selective anisotropic etch may be used to remove material from the dielectric layer 404 outside of the protected region. The mask 504 and OPL 502 may then be removed, and block 1212 may use a selective anisotropic etch to remove material from the dielectric layer 404 from horizontal surfaces, leaving the dielectric spacer 702.

Block 1214 etches down into the exposed portions of the lower alternating semiconductor layers using one or more anisotropic etches to form lower stack 1002. The anisotropic etch(es) may etch down into the surface of the semiconductor substrate 102 to form trenches. Block 1216 forms a lower transistor device on the lower stack 1002, for example by forming inner spacers on sidewalls of the sacrificial layers of the lower stack 1002, epitaxially growing source/drain structures from exposed sidewalls of the channel layers of the lower stack 1002, removing the sacrificial layers of the lower stack 1002 using an isotropic etch, and forming a lower gate stack on the exposed channel layers of the lower stack 1002. Block 1218 forms an upper transistor device on the upper stack 304, for example by masking the lower transistor device, removing the upper protective layer 402, forming inner spacers on sidewalls of the sacrificial layers of the upper stack 304, epitaxially growing source/drain structures from exposed sidewalls of the channel layers of the upper stack 304, removing the sacrificial layers of the upper stack 304 using an isotropic etch, and forming an upper gate stack on the exposed channel layers of the upper stack 304.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of stacked transistors with stepped contacts (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a lower semiconductor device over a substrate, the lower semiconductor device having a first width;
an upper semiconductor device over the lower semiconductor device, the upper semiconductor device having a second width smaller than the first width; and
a dielectric structure over the lower semiconductor device, having a first sidewall that faces the upper semiconductor device and a second sidewall that aligns vertically with a sidewall of the lower semiconductor device.

2. The semiconductor device of claim 1, further comprising a dielectric liner between the dielectric structure and the upper semiconductor device, formed from a different dielectric material as compared to the dielectric structure.

3. The semiconductor device of claim 2, wherein the dielectric liner has an ‘L’-shaped profile, with a first sidewall on channel layers of the upper semiconductor device and a second sidewall that aligns vertically with the sidewall of the lower semiconductor device and the second sidewall of the dielectric structure.

4. The semiconductor device of claim 2, wherein the dielectric liner has a top surface above a top surface of an uppermost channel layer of the upper semiconductor device.

5. The semiconductor device of claim 4, wherein the dielectric structure has a top surface above the top surface of the dielectric liner.

6. The semiconductor device of claim 2, wherein the dielectric liner has a bottom surface that aligns horizontally with a lowermost channel layer of the upper semiconductor device.

7. The semiconductor device of claim 2, wherein the dielectric liner is formed from a dielectric material selected from the group consisting of silicon dioxide, silicon nitride, aluminum oxide, titanium oxide, and silicon carbide and wherein the dielectric structure is formed from a dielectric material selected from the group consisting of silicon nitride SiN, silicoboron carbonitride, silicon oxycarbonitride.

8. The semiconductor device of claim 1, further comprising a shared gate around channel layers of the lower semiconductor device, channel layers of the upper semiconductor device, and the dielectric structure.

9. A semiconductor device, comprising:
a lower semiconductor device over a substrate, the lower semiconductor device having a first width;
an upper semiconductor device over the lower semiconductor device, the upper semiconductor device having a second width smaller than the first width;
a dielectric liner on a side of a channel layer of the upper semiconductor device, formed from a first dielectric material; and
a dielectric structure over the lower semiconductor device, having a first sidewall that faces the upper semiconductor device and the dielectric liner and a second sidewall that aligns vertically with a sidewall of the lower semiconductor device, formed from a second dielectric material different from the first dielectric material.

10. The semiconductor device of claim 9, wherein the dielectric liner has an ‘L’-shaped profile, with a first sidewall on channel layers of the upper semiconductor device and a second sidewall that aligns vertically with the sidewall of the lower semiconductor device and the second sidewall of the dielectric structure.

11. The semiconductor device of claim 9, wherein the dielectric liner has a top surface above a top surface of an uppermost channel layer of the upper semiconductor device.

12. The semiconductor device of claim 11, wherein the dielectric structure has a top surface above the top surface of the dielectric liner.

13. The semiconductor device of claim 9, wherein the dielectric liner has a bottom surface that aligns horizontally with a lowermost channel layer of the upper semiconductor device.

14. The semiconductor device of claim 9, wherein the dielectric liner is formed from a dielectric material selected from the group consisting of silicon dioxide, silicon nitride, aluminum oxide, titanium oxide, and silicon carbide and wherein the dielectric structure is formed from a dielectric material selected from the group consisting of silicon nitride, silicoboron carbonitride, silicon oxycarbonitride.

15. The semiconductor device of claim 9, further comprising a shared gate around channel layers of the lower semiconductor device, channel layers of the upper semiconductor device, and the dielectric structure.

16. A method for forming a semiconductor device, comprising:
etching an upper stack of layers from a series of alternating semiconductor layers using a top dielectric layer as a first mask;
forming a dielectric spacer on a sidewall of the upper stack of layers;
etching a lower stack of layers from the series of alternating semiconductor layers, using the top dielectric layer and the dielectric spacer as a second mask;
forming a lower transistor from the lower stack of layers; and
forming an upper transistor from the upper stack of layers.

17. The method of claim 16, further comprising forming a dielectric liner on the sidewall of the upper stack of layers before forming the dielectric spacer, wherein the dielectric liner is formed with a first dielectric material and the dielectric spacer is formed with a second dielectric material, different from the first dielectric material.

18. The method of claim 17, wherein forming the upper transistor includes forming a gate stack around channel layers of the upper stack of layers and around the dielectric spacer.

19. The method of claim 18, wherein forming the gate stack further includes forming the gate stack around channel layers of the lower stack of layers.

20. The method of claim 19, wherein forming the upper transistor includes isotropically etching away sacrificial semiconductor layers of the upper stack of layers to expose a sidewall of the dielectric liner between the channel layers of the upper stack.
